(19) United States
(12) Patent Application Publication
(10) Pub. No.: US 2025/0201568 A1
(43) Pub. Date: Jun. 19, 2025

(54) METHOD AND CHEMICAL VAPOR DEPOSITION APPARATUS FOR MANUFACTURING SEMICONDUCTOR DEVICE

(71) Applicant: TAIWAN SEMICONDUCTOR MANUFACTURING COMPANY, LTD., Hsinchu (TW)

(72) Inventors: Tsz-Mei KWOK, Hsinchu City (TW); Ming-Hua YU, Hsinchu City (TW); Chii-Horng LI, Hsinchu County (TW)

(73) Assignee: TAIWAN SEMICONDUCTOR MANUFACTURING COMPANY, LTD., Hsinchu (TW)

(21) Appl. No.: 18/402,984

(22) Filed: Jan. 3, 2024

Related U.S. Application Data
(60) Provisional application No. 63/610,398, filed on Dec. 14, 2023.

(51) Int. Cl. H01L 21/3065; H01L 21/02

(52) U.S. Cl. CPC H01L 21/3065; H01L 21/02573; H01L 21/0262

(57) ABSTRACT

A method for manufacturing a semiconductor device is provided. The method includes etching a source/drain recess in a semiconductor substrate and performing an epitaxy process to form a source/drain epitaxial structure in the source/drain recess. The epitaxy process comprises a plurality of cycles, each of the cycles comprises depositing a semiconductor material by introducing a plasma-phase precursor and a gas-phase precursor to the semiconductor substrate.

### PRIORITY CLAIM AND CROSS-REFERENCE

This application claims priority to U.S. Provisional Application Ser. No. 63/610,398, filed Dec. 14, 2023, which is herein incorporated by reference.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process provides benefits by increasing production efficiency and lowering associated costs.

Such scaling down has also increased the complexity of processing and manufacturing ICs and, for these advances to be realized, similar developments in IC processing and manufacturing are desired. For example, a three dimensional transistor, such as a fin-like field-effect transistor (FinFET), has been introduced to replace a planar transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 are cross-sectional views illustrating a method for manufacturing a semiconductor device at various stages in accordance with some embodiments.

FIG. 9 illustrates a chemical vapor deposition apparatus for manufacturing a semiconductor device at various stages in accordance with some embodiments.

FIG. 10 is a signal sequence diagram for operating a chemical vapor deposition apparatus according to some embodiments of the present disclosure.

FIG. 11 is a cross-sectional view a semiconductor device at a stage of manufacture in accordance with some embodiments.

FIG. 12 illustrates a chemical vapor deposition apparatus for manufacturing a semiconductor device at various stages in accordance with some embodiments.

FIG. 13 illustrates a chemical vapor deposition apparatus for manufacturing a semiconductor device at various stages in accordance with some embodiments.

FIG. 14 illustrates a chemical vapor deposition apparatus for manufacturing a semiconductor device at various stages in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

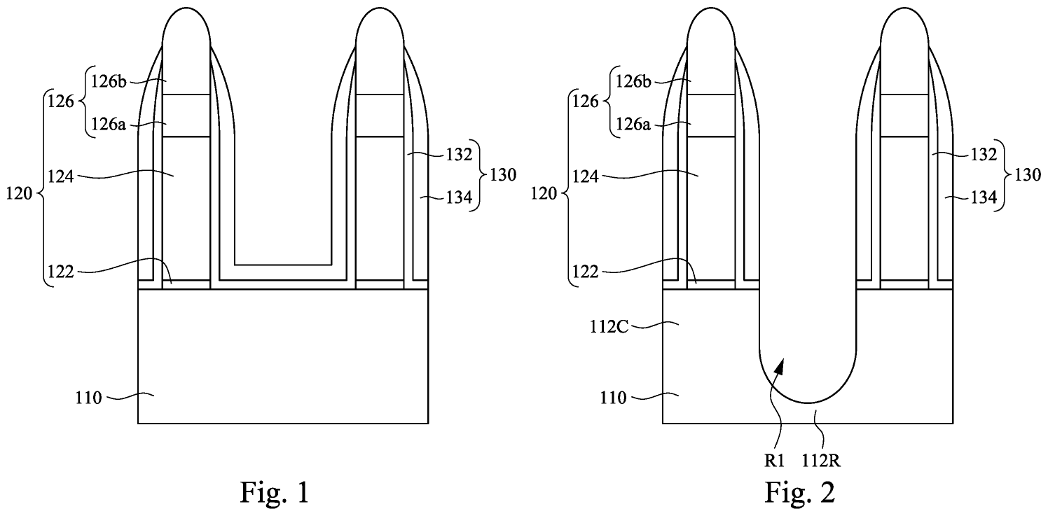

FIGS. 1-8 illustrate a method of manufacturing a semiconductor device at various stages in accordance with some embodiments. It is understood that additional steps may be provided before, during, and after the steps shown in FIGS. 1-8, and some of the steps described below can be replaced or eliminated for additional embodiments of the method. The order of the operations/processes may be interchangeable.

Reference is made to FIG. 1. A semiconductor substrate 110 is provided. The semiconductor substrate 110 may be a bulk silicon substrate. Alternatively, the semiconductor substrate 110 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible substrates 110 also include a silicon-on-insulator (SOI) substrate. SOI substrates are fabricated using separation by implantation of oxygen (SIMOX), wafer bonding, and/or other suitable methods.

The semiconductor substrate 110 may also include various doped regions. The doped regions may be doped with p-type dopants, such as boron or BF₂; n-type dopants, such as phosphorus or arsenic; or combinations thereof. The doped regions may be formed directly on the substrate 110, in a P-well structure, in an N-well structure, in a dual-well structure, and/or using a raised structure. The substrate 110 may further include various active regions, such as regions configured for an N-type metal-oxide-semiconductor transistor device and regions configured for a P-type metal-oxide-semiconductor transistor device. In some embodiments, a plurality of isolation structures may be formed over the semiconductor substrate 110 for defining active regions of the substrate. The isolation structures may act as a shallow trench isolation (STI) around the semiconductor fins.

Reference is made to FIG. 2. A plurality of dummy gate structures 120 are formed over the active regions of the semiconductor substrate 110. In some embodiments, each of the dummy gate structures 120 includes a gate dielectric 122 and a dummy gate electrode 124 over the gate dielectric 122. The dummy gate electrode 124 may include polycrystalline-silicon (poly-Si) or poly-crystalline silicon-germanium (poly-SiGe). Further, the dummy gate electrode 124 may be doped poly-silicon with uniform or non-uniform doping. The gate dielectrics 122 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof.

In some embodiments, the dummy gate structures 120 may be formed by, for example, forming a stack of a gate dielectric layer and a dummy gate material layer over the semiconductor substrate 110. A patterned mask 126 is formed over the stack of gate dielectric layer and dummy gate material layer. The patterned mask 126 may be a hard mask (HM) layer patterned through suitable photolithography process. For example, the patterned mask 126 may include silicon nitride, silicon oxy nitride, the like, or the combination thereof. The patterned mask 126 may include a silicon nitride layer 126a and a silicon oxide layer 126b over the silicon nitride layer 126a. Then, the gate dielectric layer and the dummy gate material layer may be patterned using one or more etching processes, such as one or more dry plasma etching processes or one or more wet etching processes. During the etching process, the patterned mask 126 may act as an etching mask. At least one parameter, such as etchant, etching temperature, etching solution concentration, etching pressure, source power, radio frequency (RF) bias voltage, etchant flow rate, of the patterning (or etching) recipe can be tuned. For example, dry etching process, such as plasma etching, may be used to etch the dummy gate material layer and the gate dielectric layer until the active regions of the semiconductor substrate 110 are exposed.

Gate spacers 130 are formed on sidewalls of the dummy gate structures 120. Formation of the gate spacers 130 may include conformally depositing a spacer material layer on top and sidewalls of the dummy gate structures 120 over the substrate 110, and etching the spacer material layer to form the gate spacers 130. The spacer material layer may include a dielectric material such as silicon oxide, silicon nitride, silicon oxynitride, SiCN films, silicon oxycarbide, SiOCN films, and/or combinations thereof. In some embodiments, the spacer material layer includes multiple layers, such as a first spacer layer 132, a second spacer layer 134 formed over the first spacer layer 132. The first and second spacer layers 132 and 134 may include the same or different dielectric materials. By way of example, the spacer material layer may be formed by depositing a dielectric material over the gate structures DG using processes such as, CVD process, a subatmospheric CVD (SACVD) process, a flowable CVD process, an ALD process, a PVD process, or other suitable process. An anisotropic etching process may be performed on the deposited spacer material layer. Portions of the spacer material layer directly above the dummy gate structures 120 may be completely removed by this anisotropic etching process. Portions of the spacer material layer on sidewalls of the dummy gate structures 120 may remain, forming gate spacers, which are denoted as the gate spacers 130, for the sake of simplicity. In some embodiments, the gate spacers 130 may be a single-layer structure or a multi-layer structures that includes multiple layers.

Reference is made to FIG. 2. Portions of the active regions of the semiconductor substrate 110 uncovered by the dummy gate structures 120 are removed, such that each of the active regions of the semiconductor substrate 110 include a recessed portion 112R uncovered by the dummy gate structures 120 and a channel region 112C covered by the dummy gate structures 120, respectively. Through the removal, a plurality of source/drain recesses R1 are formed in the active regions of the substrate 110. The removal of the active regions of the substrate 110 may include a dry etch, a wet etch, or the combination thereof. At least one parameter, such as etchant, etching temperature, etching solution concentration, etching pressure, source power, radio frequency (RF) bias voltage, etchant flow rate, of the etching recipe can be tuned for desired profile. In some embodiments, prior to the removal of the active regions of the substrate 110, a portion of the gate spacer 130 may be consumed and removed, for example, by suitable cleaning or etching process.

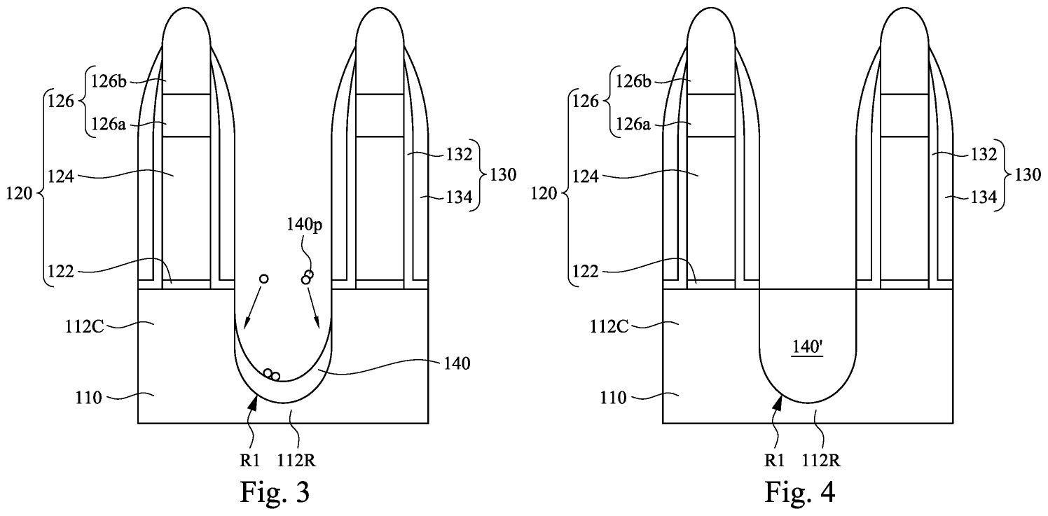

Reference is made to FIG. 3. An in-situ deposition and etching process is performed in an epitaxy chamber. That is, depositing a semiconductor material and etching the semiconductor material are performed in a same epitaxy chamber, with no vacuum break therein. For example, one or more semiconductor-containing precursors 140p are introduced into the processing chamber for growing the semiconductor epitaxial materials 140 in the source/drain recess R1. The semiconductor-containing precursors 140p may contain gaseous and/or plasma-phase precursors, which interact with the composition of the active regions (e.g., silicon). For example, the semiconductor-containing precursors 140p includes Ar, H₂, SiH₄, GeH₄, and/or GeCl₄. Subsequently, a gas-phase etchant (e.g., HCl) and/or a plasma-phase etchant (e.g., fluorine-containing (e.g., CF₄-based) plasma and/or chlorine-containing plasma) is introduced into the processing chamber for etching the semiconductor epitaxial materials 140 at sidewalls of the source/drain recess R1. Introducing the semiconductor-containing precursor 140p and the gas-phase/plasma-phase etchant may be performed with no vacuum break therein. By repeating the in-situ deposition and etching process, the semiconductor epitaxial materials 140 can fill the source/drain recess R1, and serve as a source/drain epitaxial structure 140′ as illustrated in FIG. 4 in the in-situ deposition and etching process.

In absence of introducing the plasma-phase semiconductor-containing precursors 140p, the epitaxy process may be performed by introducing the gaseous semiconductor-containing precursors 140p to a CVD chamber with a high substrate temperature (e.g., provided by the heaters 290) for gaseous precursor decomposition. This high temperature may result in strain relaxation of SiGe, dopant deactivation, and junction broadening.

In some embodiments of the present disclosure, the plasma-phase semiconductor-containing precursors 140p can be introduced to the CVD chamber. Since the plasma state has higher energy for decomposition, the substrate temperature can be lowered, which may improve dopant activation and junction abruptness of dopant, and mitigate strain relaxation.

In some embodiments where the plasma-phase etchant is used during the etch step in the in-situ deposition and etching process, the source/drain epitaxial structure 140′ may include byproducts from the plasma-phase etchant. For example, when the fluorine-based gas (CF₄) is introduced to the plasma source and turned into a fluorine-containing plasma etchant during the etch step in the in-situ deposition and etching process, the source/drain epitaxial structure 140′ may include fluorine-containing residues therein.

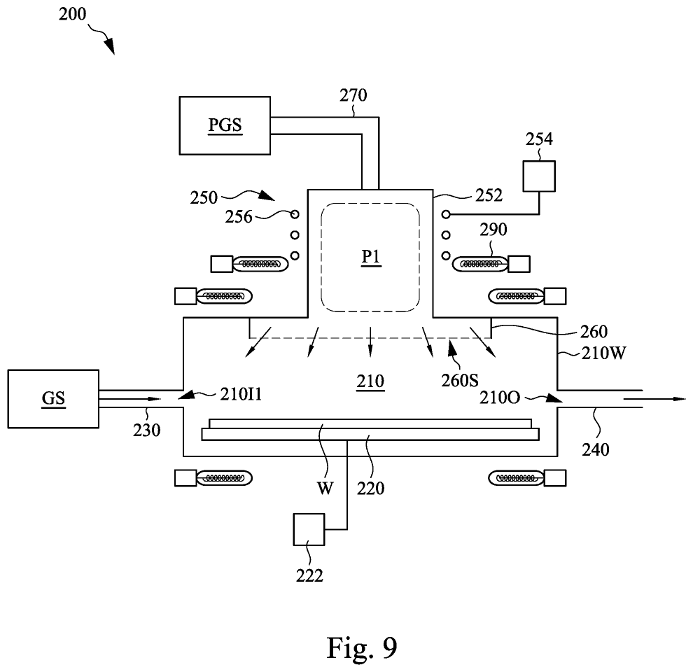

The in-situ deposition and etching process may be performed in a same processing chamber 210 of a chemical vapor deposition (CVD) apparatus 200 in FIG. 9. The processing chamber 210 of the chemical vapor deposition apparatus 200 may be coupled with a plasma source 250 for introducing the semiconductor-containing precursors 140p and the etchant in plasma phase and a gas source GS for introducing the semiconductor-containing precursors 140p and the etchant in gas phase. The plasma source 250 may be coupled with a gas supply source PGS, for receiving gases can turn the gases into plasma P1. The gas supply source PGS may contain a carrier gas (e.g., Ar), gases suitable for deposition (e.g., H₂, hydride gas (e.g., SiH₄, GeH₄), Cl-based Si source (e.g. dichlorosilane (DCS)), gases suitable for etching (e.g., H₂, Cl₂, fluorine-based gas (e.g. CF₄)), and/or suitable dopant species gas (e.g. PH₃, B₂H₆). Details of the chemical vapor deposition apparatus 200 will be illustrated later.

Reference is made to FIG. 4. A plurality of source/drain epitaxial structures 140′ are respectively formed in the source/drain recesses R1 of the active regions of the substrate 110. At least one of the source/drain epitaxial structures 140′ is formed in the source/drain recess R1 and between the dummy gate structures 120. In some embodiments, the source/drain epitaxial structures 140′ may also be referred to as epitaxy features. The source/drain epitaxial structures 140′ may be formed using one or more epitaxy or epitaxial (epi) processes, such that Si features, SiGe features, and/or other suitable features can be formed in a crystalline state on the semiconductor substrate 110. In some embodiments, lattice constants of the source/drain epitaxial structures 140 are different from lattice constants of the semiconductor substrate 110, such that channels in the channel regions 112C are strained or stressed to enable carrier mobility of the semiconductor device and enhance the device performance. In some embodiments, the source/drain epitaxial structures 140′ may include semiconductor material such as germanium (Ge) or silicon (Si); or compound semiconductor materials, such as gallium arsenide (GaAs), aluminum gallium arsenide (AlGaAs), silicon germanium (SiGe), silicon carbide (SiC), or gallium arsenide phosphide (GaAsP). In some embodiments, the source/drain epitaxial structures 140′ may include one or plural epitaxial layers, in which the plural epitaxial layers may have different compositions. For example, the source/drain epitaxial structures 140′ is depicted as including a first epitaxial layer and a second epitaxial layer, in which a composition of the first epitaxial layer is different from that of the second epitaxial layer.

The source/drain epitaxial structures 140′ may be in-situ doped. For example, doping species are introduced during depositing the semiconductor material (referring to FIG. 3). The doping species include p-type dopants, such as boron or BF₂; n-type dopants, such as phosphorus or arsenic; and/or other suitable dopants including combinations thereof. If the source/drain epitaxial structures 140′ are not in-situ doped, a second implantation process (i.e., a junction implant process) is performed to dope the source/drain epitaxial structures 140′. One or more annealing processes may be performed to activate the source/drain epitaxial structures 140′. The annealing processes include rapid thermal annealing (RTA) and/or laser annealing processes.

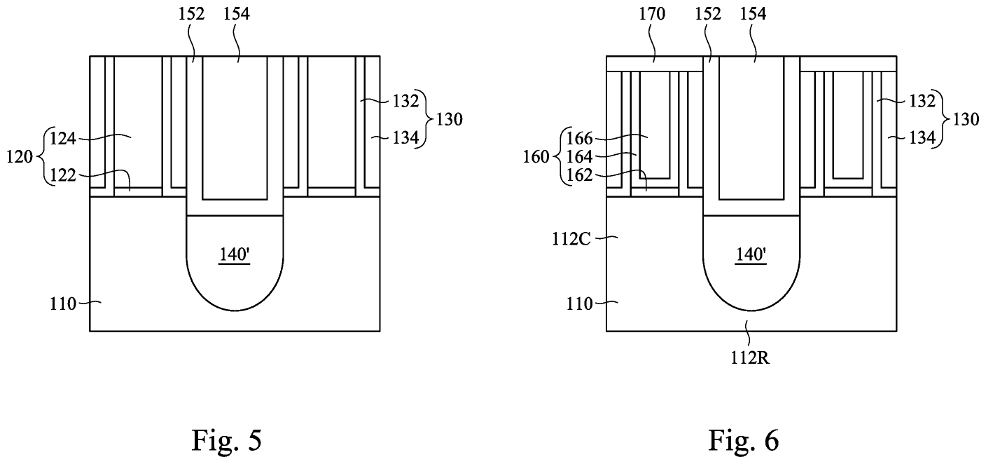

Reference is made to FIG. 5. After the source/drain epitaxial structures 140′ are formed, an interlayer dielectric (ILD) 154 is formed over the substrate 110 and surrounding the source/drain epitaxial structures 140′. The ILD 154 may include silicon oxide, oxynitride or other suitable materials. The ILD 154 includes a single layer or multiple layers. The ILD 154 can be formed by a suitable technique, such as CVD or ALD. A chemical mechanical polishing (CMP) process may be performed to remove an excess portion of the ILD 154 until reaching the dummy gate structures 120. The CMP process may also remove the patterned masks 126 of the dummy gate structures 120. After the CMP process, the dummy gate electrode 124 of the dummy gate structures 120 are exposed from the ILD 154. In some embodiments, a contact etch stop layer (CESL) 152 may be blanket formed over the substrate 110 prior to the formation of the ILD 154. In some examples, the CESL 152 includes a silicon nitride layer, silicon oxide layer, a silicon oxynitride layer, and/or other suitable materials having a different etch selectivity than the ILD 154. The CESL 152 may be formed by plasma-enhanced chemical vapor deposition (PECVD) process and/or other suitable deposition or oxidation processes.

Reference is made to FIG. 6. A replacement gate (RPG) process scheme is employed. The dummy gate structures 120 are replaced with high-k metal gate structures 160. For example, the dummy gate structures 120 (see FIG. 5) are removed to form a plurality of gate trenches. The dummy gate structures 120 are removed by a selective etch process, including a selective wet etch or a selective dry etch, and carries a substantially vertical profile of the gate spacers 130. The gate trenches expose portions of the channel region 112C of the substrate 110. Then, the high-k metal gate structures 160 are formed respectively in the gate trenches and cover the channel region 112C of the substrate 110. The high-k metal gate structure 160 may include an interfacial layer 162, a high-k dielectric layer 164 over the interfacial layer 162, and a metal-containing layer 166 over the high-k dielectric layer 164.

The interfacial layer 162 may include silicon oxides, for example, formed by thermal oxidation process. The high-k dielectric layers 164, as used and described herein, include dielectric materials having a high dielectric constant, for example, greater than that of thermal silicon oxide (˜3.9). The high-k dielectric layers 164 may include a high-K dielectric layer such as tantalum, hafnium, titanium, lanthanum, aluminum and their carbide, silicide, nitride, boride combinations. The high-k dielectric layers 164 may include other high-K dielectrics, such as HfO₂, TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-k dielectric layers 164 may be formed by ALD, PVD, CVD, oxidation, and/or other suitable methods. In some embodiments, the high-k dielectric layers 164 may include the same or different materials.

The metal-containing layer 166 may include a metal, metal alloy, metal carbide, metal silicide, metal carbide silicide, metal carbide nitride, and/or metal boride. In some embodiments, the metal-containing layer 166 may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. For example, the metal-containing layer 166 may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The work function layer(s) may be deposited by CVD, PVD, electro-plating and/or other suitable process. In some embodiments, the multi-layer metal-containing layers 166 may include the same or different materials.

After replacing the dummy gate structures 120 (see FIG. 5) with the high-k metal gate structures 160, top surfaces of the layers of the high-k metal gate structures 160 and the gate spacers 130 may be recessed, and a dielectric layer 170 may be formed over the recessed top surface of the layers of the high-k metal gate structures 160 and the gate spacers 130. The dielectric layer 170 may include a same dielectric material as that of the second spacer layer 134. In some alternative embodiments, the dielectric layer 170 may include a different dielectric material from that of the second spacer layer 134.

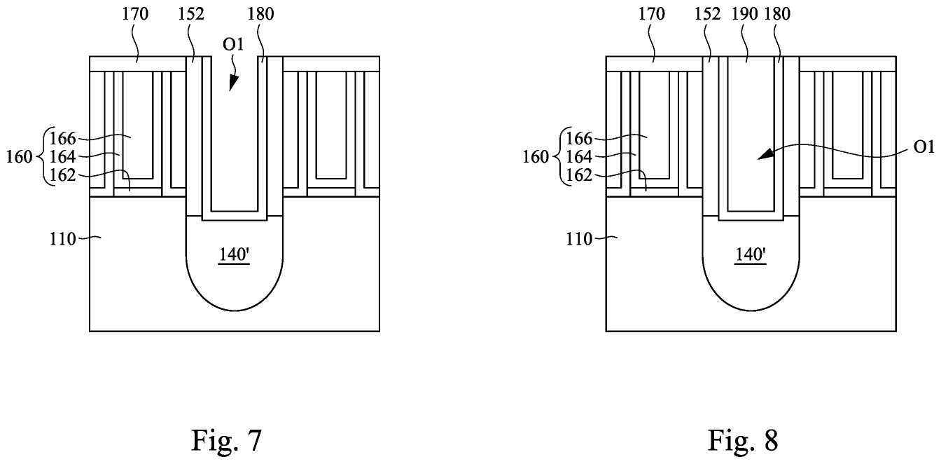

Reference is made to FIG. 7. Source/drain contact openings O1 are etched through the ILD 154 and the CESL 152 to expose surfaces of the source/drain epitaxial structures 140′. In some embodiments, a metal alloy layer 180 may be formed over the exposed surface of the source/drain epitaxial structure 140′ for reducing contact resistance. The metal alloy layer 180, which may be a silicide layer, is formed in the contact openings O1 and over the exposed surface of the source/drain epitaxial structures 140′, by a self-aligned silicide (salicide) process. The silicide process converts the surface portions of the source/drain epitaxial structures 140′ into the silicide contacts. Silicide processing involves deposition of a metal that undergoes a silicidation reaction with silicon (Si). In order to form silicide contacts on the source/drain epitaxial structures 140′, a metal material is blanket deposited on the exposed surface of the source/drain epitaxial structures 140′. After heating the wafer to a temperature at which the metal reacts with the silicon of the source/drain epitaxial structures 140′ to form contacts, unreacted metal is removed. The silicide contacts remain over the exposed surface of the source/drain epitaxial structures 140′, while unreacted metal is removed from other areas. The silicide layer may include a material selected from titanium silicide, cobalt silicide, nickel silicide, platinum silicide, nickel platinum silicide, erbium silicide, palladium silicide, combinations thereof, or other suitable materials.

In some embodiments where the source/drain epitaxial structure 140′ includes fluorine-containing residues therein, fluorine may out-diffuse to a surface of the source/drain epitaxial structure 140′ during one or more annealing processes. The surface of the source/drain epitaxial structure 140′ may be etched away during etching the source/drain contact openings O1. As a result, after etching the source/drain contact openings O1, a top portion of the source/drain epitaxy structure 140′ may have a lower fluorine concentration than that of a bottom portion of the source/drain epitaxy structure 140′ below the top portion of the source/drain epitaxy structure 140′ in some embodiments.

Reference is made to FIG. 8. A source/drain contact 190 is formed over the metal silicide layer 180. The source/drain contact 190 may also be referred to as a contact plug. In some embodiments, the source/drain contact formation step comprises depositing one or more metal materials to fill the source/drain contact opening O1. A CMP process may be performed to remove excess metal materials outside the source/drain contact opening O1, while leaving metal materials in the source/drain contact opening O1 to serve as the source/drain contact 190. The one or more metal materials may include W, Ru, Co, Cu, Ti, TiN, Ta, TaN, Mo, Ni, the like or combinations thereof. The one or more metal materials may be deposited by suitable deposition techniques (e.g., CVD, PVD, ALD, the like or combinations thereof).

FIG. 9 illustrates a CVD apparatus 200 for manufacturing a semiconductor device at various stages in accordance with some embodiments. The CVD apparatus 200.

The CVD apparatus 200 may include a processing chamber 210, a wafer stage 220, a gas supply line 230, and a gas exhaust line 240. The processing chamber 210 has a wall 210W surrounding itself. The wafer stage 220 is in the processing chamber 210 and configured to support a wafer W. The processing chamber 210 may include a gas inlet 210I1 coupled with a gas supply source GS through the gas supply line 230 and a gas outlet 2100 coupled with a gas exhaust system (e.g., a pump) through the gas exhaust line 240. The gas supply source GS may contain gases suitable for deposition and/or etching process. For example, the gas supply source GS may contain H₂, SiH₄, for gas-phase deposition, and HCl for gas-phase etching.

The CVD apparatus 200 includes a plasma source 250 coupled to the processing chamber 210. The plasma source 250 may be coupled with a gas supply source PGS through a gas supply line 270. The gas supply source PGS may contain gases suitable for forming plasma for deposition, doping, and/or etching process. The gas supply line 270 may introduce the gases from the gas supply source PGS to the cavity 252 of the plasma source 250. For example, the gas supply source PGS may contain a carrier gas (e.g., Ar), gases suitable for deposition (e.g., H₂, hydride gas (e.g., SiH₄, GeH₄), Cl-based Si source (e.g. dichlorosilane (DCS)), gases suitable for etching (e.g., H₂, Cl₂, fluorine-based gas (e.g. CF₄)), and/or suitable dopant species gas (e.g. PH₃, B₂H₆). The flows of the carrier gas, the gases suitable for deposition, the gases suitable for etching, and the dopant species gas from the gas supply source PGS to the plasma source 250 can be controlled independently. In the present embodiments, the plasma source 250 is arranged above the processing chamber 210, on a top side of the wall 210W.

In some embodiments, the gas supply source PGS and the gas supply source GS may contain the same precursor gas for deposition, such as a mixture of H₂ and SiH₄. In some other embodiments, the gas supply source PGS and the gas supply source GS may contain different precursor gases for deposition. In some embodiments, the gas supply source PGS and the gas supply source GS may contain the same etchant gases for etching. In some other embodiments, the gas supply source PGS and the gas supply source GS may contain different etchant gases for etching.

After the carrier gas, the gases suitable for deposition, the gases suitable for etching, and the dopant species gas are introduced from the gas supply source PGS to the plasma source 250, the plasma source 250 may turn the carrier gas, the gases suitable for deposition, the gases suitable for etching, and the dopant species gas into the plasma P1. In some examples, the plasma P1 may include ions and radicals, such as H, H⁺, SiH₂. The plasma source 250 may be an inductively coupled plasma (ICP) source, an electron cyclotron resonance (ECR) plasma source, a toroidal plasma source. The plasma source 250 may also be referred to as a plasma reactor, a plasma generator in the context. For example, the plasma source 250 may include a cavity 252 for receiving the carrier gas, the gases suitable for deposition, the gases suitable for etching, and the dopant species gas from the gas supply source PGS. In some embodiments where the plasma source 250 is the ICP source, the plasma source 250 is associated with a power supply 254 couple with a coil 256 surrounding the cavity 252 in order to generate the plasma P1 in the cavity 252 of the plasma source 250. In some alternative embodiments, the cavity 252 may act as a resonator, in which the waves bounce back and forth between the walls of the cavity to form plasma P1 in the cavity 252.

The cavity 252 of the plasma source 250 may be fluidly connected with the processing chamber 210. In the present embodiments, the cavity 252 of the plasma source 250 is directly coupled with the processing chamber 210 without any additional elements, thereby enlarging a cross-sectional area that the plasma P1 flow through into the processing chamber 210. In some alternative embodiments, the cavity 252 of the plasma source 250 may be coupled with the processing chamber 210 through suitable elements.

The CVD apparatus 200 includes the gas distribution plate 260 near the plasma source 250. The gas distribution plate 260 may also be referred to as showerhead. The gas distribution plate 260 includes a plurality of apertures 260S formed through the thickness of the gas distribution plate 260 to spread plasma P1 generated in the plasma source 250. The apertures 260S are designed to ensure uniform distribution of the plasma P1 to the wafer W. Various designs of distribution of the apertures 260S could be adopted according to other parts of the tool. In some embodiments, the apertures 260S are evenly distributed across the diameter of the gas distribution plate 260 to ensure uniform distribution of the plasma P1 to the wafer W. In some embodiments, the apertures 260S are unevenly distributed across the diameter of the gas distribution plate 260. The plasma P1 flowing through the apertures 260S are distributed across the wafer W in the processing chamber 210.

The gas distribution plate 260 may be electrically grounded in some embodiments. The grounded gas distribution plate 260 is configured to filter ions (e.g., H⁺) generated in the plasma source 360 before entering the processing chamber 210, while allowing electrically neutral radicals (e.g., H, SiH₂) to enter the processing chamber 210 to participate in the epitaxy process. The relative concentration of ions in the processing chamber 210 is thus reduced. In some alternative embodiments, the distribution plate 260 may not be electrically grounded.

In some embodiments, the wafer W may be electrically biased to attract or repel ions generated in the plasma P1, depending on the application. For example, a power supply 222 may be provided to apply RF power to an electrode of the wafer stage 220 during the process to bias the wafer W to attract deposition/etch material ions. Further, the power supply 222 may be configured to apply RF power to the electrode of the wafer stage 220 to couple the auxiliary energy to the plasma P1. The bias operation enables more directional supply of precursors and/or etchant, to allow anisotropic growth and/or etching.

The CVD apparatus 200 may further include heaters 290 over and/or below the wafer stage 220 for provide thermal control to the wafer W during processing. The heaters 290 may include lamps. For example, the heaters 290 are arranged above the processing chamber 210, on a top side of the wall 210W. The heaters 290 may also be arranged below the processing chamber 210, at a bottom side of the wall 210W. The heaters 290 may be arranged for providing uniform thermal distribution across the wafer W. The heaters 290 may also be arranged for providing heat to the wafer W. The heaters 290 may have a circular shape around the plasma source 250. In the present embodiments, the wall 210W defines a flat shape for the processing chamber 210. In some alternative embodiments, the wall 210W may define other shapes for the processing chamber 210.

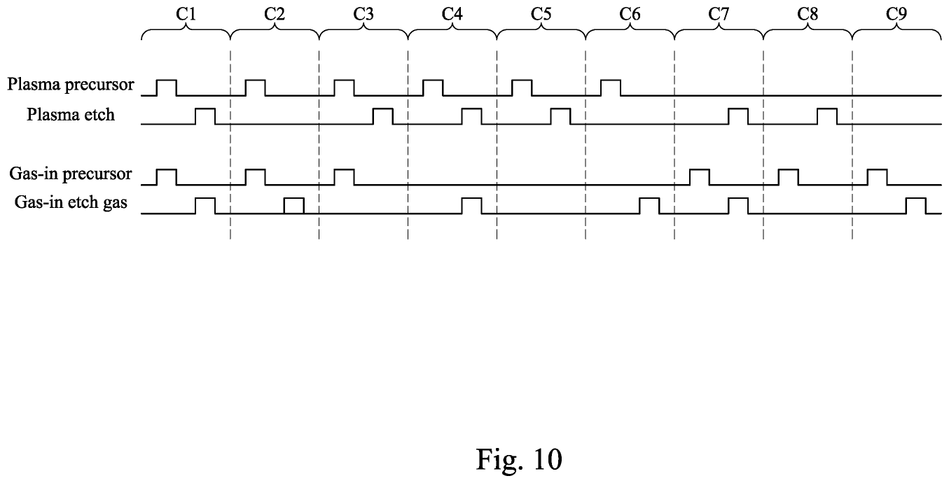

FIG. 10 is a signal sequence diagram for operating a chemical vapor deposition apparatus according to some embodiments of the present disclosure. During the in-situ deposition and etching process illustrated in FIGS. 3-4, a plurality of cycles are repeated, and each cycle may include a deposition process and an etch process. Gas-phase semiconductor-containing precursors 140p from the gas source GS (or the gas supply line 230) (referring to FIG. 9), plasma-phase semiconductor-containing precursors 140p from the plasma source 250 (referring to FIG. 9), or the combination thereof can be introduced to the processing chamber 210 for the deposition process. In examples of in-situ doping, when the plasma-phase semiconductor-containing precursors 140p is introduced from the plasma source 250 to the processing chamber 210, dopant species (e.g. PH₃, B₂H₆) may also introduced from the plasma source 250 to the processing chamber 210. And, gas-phase etchants from the gas source GS (referring to FIG. 9), plasma-phase etchants from the plasma source 250 (referring to FIG. 9), or the combination thereof can be introduced to the processing chamber 210 for the etch process.

In FIG. 10, cycles C1-C9 are shown. The cycle C1 include a deposition process using both gas-phase semiconductor-containing precursors 140p and plasma-phase semiconductor-containing precursors 140p, followed by an etching process using both gas-phase etchants and plasma-phase etchants. The cycle C2 include a deposition process using both gas-phase semiconductor-containing precursors 140p and plasma-phase semiconductor-containing precursors 140p, followed by an etching process using the gas-phase etchants without the plasma-phase etchants. The cycle C3 include a deposition process using both gas-phase semiconductor-containing precursors 140p and plasma-phase semiconductor-containing precursors 140p, followed by an etching process using the plasma-phase etchants without the gas-phase etchants. The cycle C4 include a deposition process using the plasma-phase semiconductor-containing precursors 140p without the gas-phase semiconductor-containing precursors 140p, followed by an etching process using both gas-phase etchants and plasma-phase etchants. The cycle C5 include a deposition process using the plasma-phase semiconductor-containing precursors 140p without the gas-phase semiconductor-containing precursors 140p, followed by an etching process using the plasma-phase etchants without the gas-phase etchants. The cycle C6 include a deposition process using the plasma-phase semiconductor-containing precursors 140p without the gas-phase semiconductor-containing precursors 140p, followed by an etching process using the gas-phase etchants without the plasma-phase etchants. The cycle C7 include a deposition process using the gas-phase semiconductor-containing precursors 140p without the plasma-phase semiconductor-containing precursors 140p, followed by an etching process using both gas-phase etchants and plasma-phase etchants. The cycle C8 include a deposition process using the gas-phase semiconductor-containing precursors 140p without the plasma-phase semiconductor-containing precursors 140p, followed by an etching process using the plasma-phase etchants without the gas-phase etchants. The cycle C9 include a deposition process using the gas-phase semiconductor-containing precursors 140p without the plasma-phase semiconductor-containing precursors 140p, followed by an etching process using the gas-phase etchants without the plasma-phase etchants. The in-situ deposition and etching process illustrated in FIGS. 3-4 may be performed by repeating one or more of the cycles C1-C9. In some embodiments where the in-situ deposition and etching process includes two or more of the cycles C1-C9, the sequence of the cycles C1-C9 may be interchangeable.

When the deposition step is enhanced by plasma, as the precursor decomposition can be achieved by the high energy in plasma, the temperature of the wafer W (referring to FIG. 10), which may be controlled by the heaters 290, can be lowed. Accordingly, the temperature of the wafer W (referring to FIG. 10) may vary according to the plasma density of the plasma generated in the deposition step and/or the flow rate of the gas-phase precursors in the deposition step.

In FIG. 10, the cycles C1-C6 include plasma-enhanced deposition steps, in which the cycles C4-C6 is more plasma-enhanced than the cycles C1-C3, and the cycles C7-C9 are not enhanced by the plasma. For example, a flow rate of the gas-phase precursor in the deposition steps of the cycles C4-C6 may be lower than a flow rate of the gas-phase precursor in the deposition steps of the cycles C1-C3, and a flow rate of the gas-phase precursor in the deposition steps of the cycles C1-C3 is lower than a flow rate of the gas-phase precursor in the deposition steps of the cycles C7-C9. Thus, the plasma density of the plasma generated in the deposition step in the cycles C4-C6 may be greater than the plasma density of the plasma generated in the deposition step in the cycles C1-C3, and the plasma density of the plasma generated in the deposition step in the cycles C1-C3 may be greater than the plasma density of the plasma generated in the deposition step in the cycles C7-C9. As a result, by using the heaters 290, the temperature of the wafer W (referring to FIG. 10) in the deposition steps of the cycles C4-C6 may be controlled to be lower than the temperature of the wafer W (referring to FIG. 10) in the deposition steps of the cycles C1-C3, and the temperature of the wafer W (referring to FIG. 10) in the deposition steps of the cycles C1-C3 can be controlled to be lower than the temperature of the wafer W (referring to FIG. 10) in the deposition steps of the cycles C7-C9.

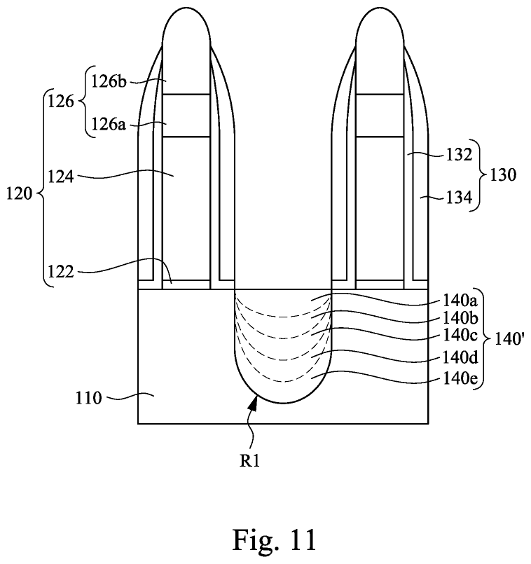

FIG. 11 is a cross-sectional view a semiconductor device at a stage of manufacture in accordance with some embodiments. Details of the present embodiments are similar to those illustrated in FIGS. 3-4, except that the source/drain epitaxial structures 140′ include a plurality of epitaxial materials 140a-140e, each of the epitaxial materials 140a-140e is grown by repeating one or more of the cycles C1-C9 in FIG. 10. The cycles for growing two or more of the epitaxial materials 140a-140e may be different from each other. For example, the epitaxial material 140a is grown by repeating the cycle C1, the epitaxial material 140b is grown by repeating the cycle C2, the epitaxial material 140c is grown by repeating the cycle C3, the epitaxial material 140d is grown by repeating the cycle C4, and the epitaxial material 140e is grown by repeating the cycle C5. In some embodiments where the plasma-phase etchant is used during the etch step in each cycle, etch-byproducts may be present on a top surface of the corresponding epitaxial material. For example, because the cycles C1 and C3-C5 use the plasma-phase etchant, fluorine-containing residues may be present on top surfaces of the epitaxial materials 140a, 140c, 140d, and 140e, but may be absent from the top surface of the epitaxial material 140b, because the cycle C2 is free of the plasma-phase etchant. Stated differently, fluorine-containing residues may be present at the interface between the epitaxial material 140a and 140b, at the interface between the epitaxial material 140c and 140d, at the interface between the epitaxial material 140d and 140e, and at the top surface of the epitaxial material 140e. In some other embodiments, depending on the type of the repeating cycles, the fluorine-containing residues can be found at one or more of the interfaces between any two of the epitaxial materials 140a-140e, while other interfaces therebetween are free from the fluorine-containing residues.

In some embodiments, the flow rate of the gas-phase precursor for the cycles C4 and C5 growing the epitaxial materials 140d and 140e is lower than the flow rate of the gas-phase precursor for the cycles C1-C3 growing the epitaxial materials 140a-140c. Thus, the plasma density of the plasma-phase precursor for the cycles C4 and C5 growing the epitaxial materials 140d and 140e is higher than the plasma density of the plasma-phase precursor for the cycles C1-C3 growing the epitaxial materials 140a-140c. As the precursor decomposition can be achieved by the high energy in plasma, by using the heaters 290, a temperature of the semiconductor substrate during the deposition step of the cycles C4 and C5 can be controlled to be lower than a temperature of the semiconductor substrate during the deposition step of the cycles C1-C3. Other details of the present embodiments are similar to those illustrated above, and thereto not repeated herein.

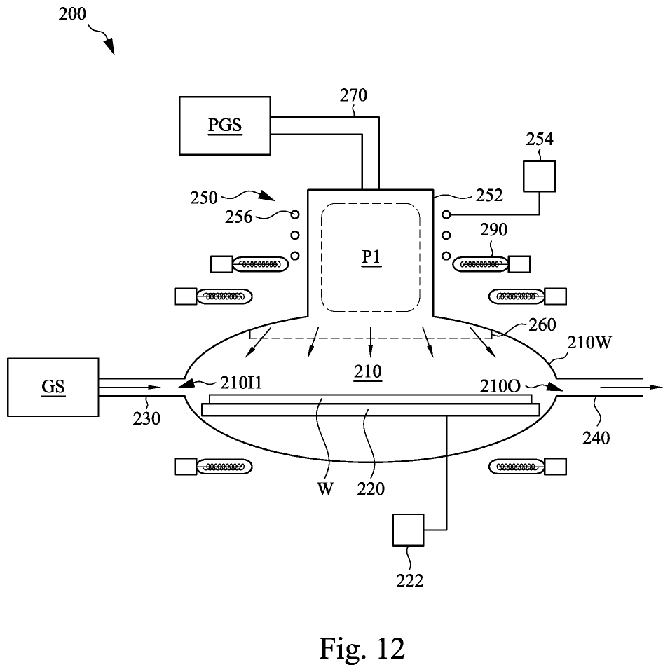

FIG. 12 illustrates a CVD apparatus 200 for manufacturing a semiconductor device at various stages in accordance with some embodiments. Details of the present embodiments are similar to those illustrated in FIG. 9, except that the wall 210W defines a dome shape for the processing chamber 210. For example, the wall 210W has a ellipse shape. In the present embodiments, the plasma source 250 is arranged on a top end of the dome-shaped processing chamber 210, and the gas inlet 210I1 and the gas outlet 2100 are arranged at lateral ends of the dome-shaped processing chamber 210. Other details of the present embodiments are similar to those illustrated above, and therefore not repeated herein.

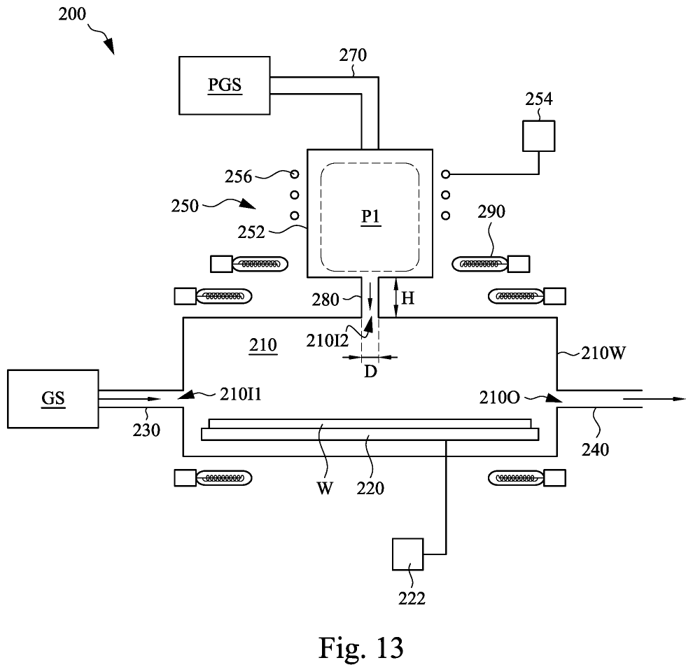

FIG. 13 illustrates a CVD apparatus 200 for manufacturing a semiconductor device at various stages in accordance with some embodiments. Details of the present embodiments are similar to those illustrated in FIG. 9, except that the CVD apparatus further include a plasma supply line 280 connecting the plasma source 250 to the processing chamber 210. For example, the processing chamber 210 has an inlet 210I2 on the top side of the wall 210W and coupled with the plasma supply line 280 connected to the plasma source 250. Thus, the plasma P1 is injected into the processing chamber 210 through a path (i.e. the plasma supply line 280) having a length H and a width/diameter D. The length H may be in a range from about 10 millimeters to about 100 millimeters. The width/diameter D may be in a range from about 10 millimeters to about 100 millimeters. If the length H is greater than about 100 millimeters, plasma may be neutralized, and plasma density decreases. If the width/diameter D is less than 10 millimeters, the plasma distribution becomes uneven. Other details of the present embodiments are similar to those illustrated above, and therefore not repeated herein.

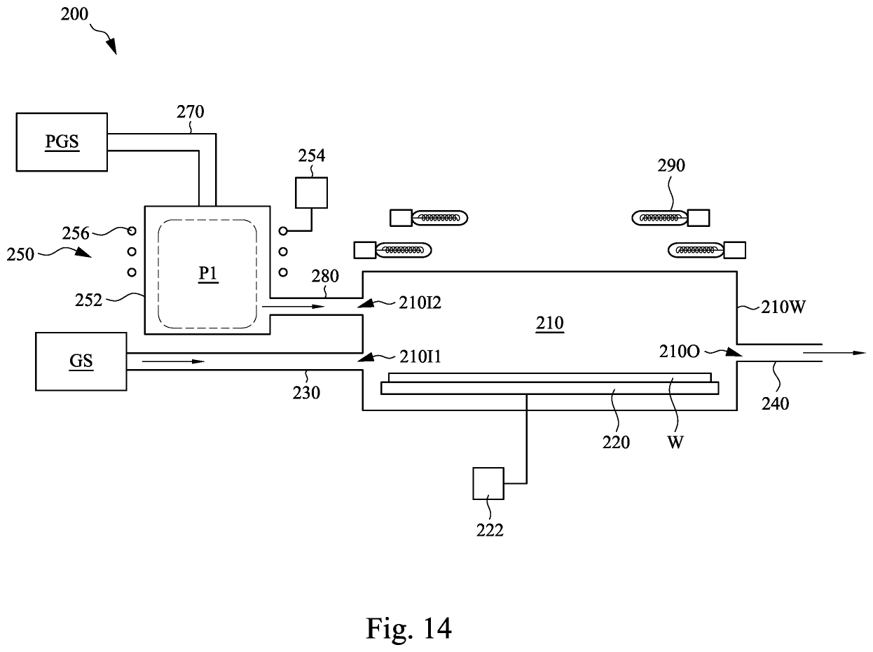

FIG. 14 illustrates a CVD apparatus for manufacturing a semiconductor device at various stages in accordance with some embodiments. Details of the present embodiments are similar to those illustrated in FIG. 13, except that the plasma source 250 is arranged next to the processing chamber 210, on a lateral side of the wall 210W. For example, the processing chamber 210 has an inlet 210I2 on the lateral side of the wall 210W coupled with the plasma supply line 280 connected to the plasma source 250. In some embodiments, the inlets 210I1 and 210I2 are on the same lateral side of the wall 210W, opposite to the lateral side of the wall 210W where the gas outlet 2100 is disposed. Other details of the present embodiments are similar to those illustrated above, and therefore not repeated herein.

Based on the above discussions, it can be seen that the present disclosure offers advantages over semiconductor devices. It is understood, however, that other embodiments may offer additional advantages, and not all advantages are necessarily disclosed herein, and that no particular advantage is required for all embodiments.

One advantage is that a plasma-enhanced epitaxy method is used for source/drain epitaxy of semiconductor devices. By incorporating a plasma unit in CVD apparatus, radicals and ions generated can participate in the epitaxy process. Another advantage is that the plasma-enhanced epitaxy method allows low substrate temperature, which may improve dopant activation and junction abruptness of dopant, and mitigate strain relaxation. Still another advantage is that when the substrate bias is applied, the plasma-enhanced epitaxy method enables more directional supply of precursors, to allow anisotropic growth. Still another advantage is that the plasma-enhanced epitaxy method can be implemented in a planar transistor, a multi-gate device (e.g., FinFET device or Gate-All-Around (GAA) device comprising nanosheet or nanowire), or the like. Still another advantage is that both deposition and in-situ etching can employ this plasma enhanced method.

According to some embodiments of the present disclosure, a method for manufacturing a semiconductor device is provided. The method includes etching a source/drain recess in a semiconductor substrate and performing an epitaxy process to form a source/drain epitaxial structure in the source/drain recess. The epitaxy process comprises a plurality of cycles, each of the cycles comprises depositing a semiconductor material by introducing a plasma-phase precursor and a gas-phase precursor to the semiconductor substrate.

According to some embodiments of the present disclosure, a method for manufacturing a semiconductor device is provided. The method includes placing a semiconductor substrate in an epitaxy chamber; performing a first deposition step to form a first portion of a source/drain epitaxial structure over the semiconductor substrate; and performing a second deposition step to form a second portion of the source/drain epitaxial structure over the semiconductor substrate. Each of the first and second deposition steps comprises: introducing a first precursor gas to a plasma source; using the plasma source to turn the first precursor gas into a plasma; introducing the plasma to the epitaxy chamber; and introducing a second precursor gas to the epitaxy chamber, wherein a plasma density of the plasma generated in the first deposition step is greater than a plasma density of the plasma generated in the second deposition step.

According to some embodiments of the present disclosure, a chemical vapor deposition apparatus for manufacturing a semiconductor device is provided. The chemical vapor deposition apparatus comprises a processing chamber; a wafer stage in the processing chamber; a first gas supply line connecting a first gas source to the processing chamber; a plasma source coupled with the processing chamber; a second gas supply line connecting a second gas source to the plasma source; and a heater surrounding the processing chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
etching a source/drain recess in a semiconductor substrate; and
performing an epitaxy process to form a source/drain epitaxial structure in the source/drain recess, wherein the epitaxy process comprises:
depositing a semiconductor material by introducing a plasma-phase precursor and a gas-phase precursor to the semiconductor substrate.

2. The method of claim 1, wherein the plasma-phase precursor is introduced from a plasma cavity coupled to an epitaxy chamber, and the epitaxy process further comprises:
introducing a dopant species from the plasma cavity to the semiconductor substrate during depositing the semiconductor material.

3. The method of claim 1, wherein the plasma-phase precursor and the gas-phase precursor comprise a same material.

4. The method of claim 1, wherein the epitaxy process further comprises:
etching the semiconductor material by introducing a plasma-phase etchant, a gas-phase etchant, or a combination thereof, to the semiconductor substrate.

5. The method of claim 4, wherein the plasma-phase precursor is introduced from a plasma cavity coupled to an epitaxy chamber, and the plasma-phase etchant is introduced from the plasma cavity.

6. The method of claim 1, wherein the plasma-phase precursor is introduced from a plasma cavity coupled to a first inlet of an epitaxy chamber, and the gas-phase precursor is introduced from a gas source coupled to a second inlet of the epitaxy chamber.

7. A method for manufacturing a semiconductor device, comprising:
placing a semiconductor substrate in an epitaxy chamber; and
performing at least one deposition step to form at least one first portion of a source/drain epitaxial structure over the semiconductor substrate, wherein the at least one deposition step comprises:
introducing a first precursor gas to a plasma source;
using the plasma source to turn the first precursor gas into a plasma-phase precursor;
introducing the plasma-phase precursor to the epitaxy chamber; and
introducing a second precursor gas to the epitaxy chamber.

8. The method of claim 7, wherein the at least one deposition step comprises:
a first deposition step to form a first part of the at least one first portion of the source/drain epitaxial structure over the semiconductor substrate; and
a second deposition step to form a second part of the at least one first portion of the source/drain epitaxial structure over the semiconductor substrate, wherein a plasma density of the plasma-phase precursor in the first deposition step is different than a plasma density of the plasma-phase precursor in the second deposition step.

9. The method of claim 8, wherein a temperature of the semiconductor substrate during the first deposition step is lower than a temperature of the semiconductor substrate during the second deposition step.

10. The method of claim 8, wherein a flow rate of the second precursor gas during the first deposition step is less than a flow rate of the second precursor gas during the second deposition step.

11. The method of claim 7, further comprising:
performing a gas-phase deposition step to form a second portion of the source/drain epitaxial structure over the semiconductor substrate, wherein the gas-phase deposition step comprises introducing the second precursor gas to the epitaxy chamber, and the gas-phase deposition step does not comprise introducing the plasma-phase precursor to the epitaxy chamber.

12. The method of claim 7, further comprising:
performing a plasma-phase deposition step to form a third portion of the source/drain epitaxial structure over the semiconductor substrate, wherein the plasma-phase deposition step comprises introducing the plasma-phase precursor to the epitaxy chamber, and the plasma-phase deposition step does not comprise introducing the second precursor gas to the epitaxy chamber.

13. The method of claim 7, wherein further comprising:
introducing a dopant species to the plasma source during the at least one deposition step.

14. The method of claim 7, further comprising:
providing a substrate bias to the semiconductor substrate during the at least one deposition step.

15. The method of claim 7, further comprising:
filtering the plasma-phase precursor by grounding a gas distribution plate in the epitaxy chamber during the at least one deposition step.

16. The method of claim 7, further comprising:
performing at least one an etching step to etch the at least one first portion of the source/drain epitaxial structure after the at least one deposition step:
introducing an etchant gas to the plasma source;
using the plasma source to turn to the etchant gas into a plasma-phase etchant; and
introducing the plasma-phase etchant to the epitaxy chamber.

17. The method of claim 16, wherein the etchant gas comprises a fluorine-based gas.

18. A chemical vapor deposition apparatus for manufacturing a semiconductor device, comprising:
a processing chamber;
a wafer stage in the processing chamber;
a first gas supply line connecting a first gas source to the processing chamber;
a plasma source coupled with the processing chamber;
a second gas supply line connecting a second gas source to the plasma source; and
a heater surrounding the processing chamber.

19. The chemical vapor deposition apparatus of claim 18, further comprising:
a plasma supply line connecting a cavity of the plasma source to the processing chamber.

20. The chemical vapor deposition apparatus of claim 18, wherein a cavity of the plasma source is directly coupled to the processing chamber.
